(19) United States
(12) Patent Application Publication
(10) Pub. No.: US 2017/0309837 A1
(43) Pub. Date: Oct. 26, 2017

(54) POLYMER AND ORGANIC LIGHT-EMITTING DEVICE

(71) Applicants: Cambridge Display Technology Limited, Godmanchester (GB); Sumitomo Chemical Company Limited, Tokyo (JP)

(72) Inventors: Florence Bourcet, Godmanchester (GB); Annette Steudel, Dresden (DE); Richard J Wilson, Cambridge (GB)

(73) Assignees: Cambridge Display Technology Limited, Godmanchester (GB); Sumitomo Chemical Company Limited, Tokyo (JP)

(21) Appl. No.: 15/100,106

(22) PCT Filed: Nov. 28, 2014
(86) PCT No.: PCT/GB2014/053551

§ 371 Date: May 27, 2016

(51) Int. Cl. H01L 51/00; C08G 61/12; C08G 73/06; C09K 11/06; C08K 5/56

(52) U.S. Cl. CPC H01L 51/0085; H01L 51/0035; C08K 5/56; C08G 73/06; C09K 11/06; C08G 61/122; C08G 2261/95; C09K 2211/1466

(57) ABSTRACT

A composition comprising a phosphorescent compound of formula (I) and a polymer comprising a repeat unit of formula (II) Ar¹ is an aryl or heteroaryl group. R² is a substituent. A is independently in each occurrence N or CR³ wherein R³ is H or a substituent. M is a transition metal or metal ion. x is a positive integer of at least 1. y is 0 or a positive integer. L¹ is a mono- or polydentate ligand. R¹ is a substituent. z is 0 or a positive integer. X is O or S. The phosphorescent compound of formula (I) may be mixed with the polymer or may be covalently bound thereto. The composition may be used in the light-emitting layer of an organic light-emitting device.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

A hole-transporting layer may be provided between the anode and light-emitting layer of an OLED.

Suitable light-emitting materials include small molecule, polymeric and dendrimeric materials. Suitable light-emitting polymers include poly(arylene vinylenes) such as poly(p-phenylene vinylenes) and polymers containing arylene repeat units, such as fluorene repeat units. Blue light-emitting fluorene homopolymer is disclosed in WO WO 2010/085676 discloses host materials for electrophosphorescent devices. A copolymer formed by copolymerization of 1,6-bis(3-(4,4,5,5-tetramethyl-[1,3,2]-dioxaborolan-2-yl)phenoxyl)hexane and 2-(4-(3-(3,6-dibromocarbazol-9-yl)propyl)phenyl)-4,6-di(3-methylphenyl)-1,3,5-triazine is disclosed.

WO 2008/025997 discloses the following monomer for use in preparation of a polymeric host:

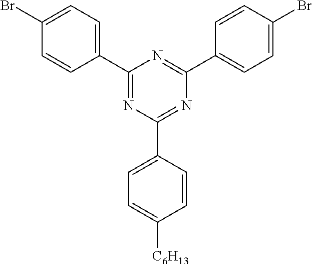

WO 2013/191088 discloses a high molecular compound including a group of formula (11):

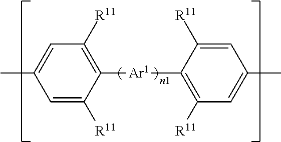

wherein n1 is an integer of 1-3; Ar¹ is an arylene group, a divalent aromatic heterocyclic group, or a divalent aromatic amine residue; and R¹¹ is H, alkyl, aryl, heteroaryl or aralkyl, and at least three of the groups R¹¹ are alkyl, aryl, heteroaryl or aralkyl.

EP1245659 discloses a polymer having a phosphorescent metal complex in the main chain or in a side chain of the polymer.

Huang et al, Polymer (2009), 50(25), 5945-5958 discloses a polymer having fluorene repeat units, dibenzothiophene repeat units and a benzimidazole-based iridium complex repeat unit.

Mikroyannidis et al, J. Poly. Sci., Part A: Polymer Chemistry (2006), 44(23), 6790-6800 discloses poly(fluorene vinylene-alt-dibenzothiophene vinylene)s. OLEDs containing these polymers showed electroluminescence with maxima at 530 and 540 nm.

Mikroyannidis et al, Synth. Met. 2004, 142(1-3), 113-120 discloses fluorescent poly(p-phenylenes) bearing dibenzothiophene moieties along the main chain and having a photoluminescence maximum near 510 nm.

Yang et al, Synth. Met. 2003, 135-136, 183-184 discloses copolymers of fluorene and dibenzothiophene, and fluorescent OLEDs formed for these copolymers.

Yang et al, J. Mater. Chem. 2003, 13(6), 1351-1355 discloses copolymers of 9,9-dioctylfluorene and dibenzothiophene.

Nemoto, J. Poly. Sci., Part A: Polymer Chemistry 2003, 41(10), 1521-1526 discloses a polymer formed by Suzuki polycondensation of a 2,8-diboronic ester dibenzothiophene with 2,7-dibromo-9,9-dioctylfluorene and 3,6-dibromo-9-octylcarbazole or 1,4-dibromo-2,5-dioctyloxybenzene.

### SUMMARY OF THE INVENTION

In a first aspect the invention provides a composition comprising a phosphorescent compound of formula (I) and a polymer comprising a repeat unit of formula (II)

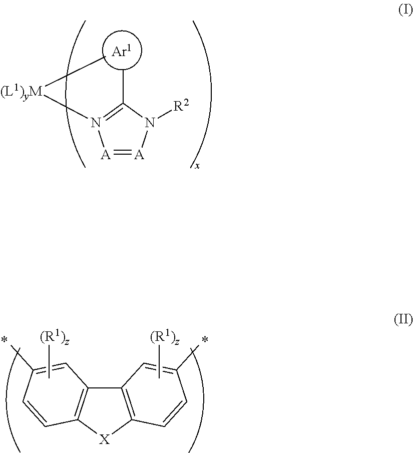

wherein:

Ar¹ is an aryl or heteroaryl group that may be unsubstituted or substituted with one or more substituents;

R² is a substituent;

A is independently in each occurrence N or CR³ wherein R³ is H or a substituent;

M is a transition metal or metal ion;

x is a positive integer of at least 1;

y is 0 or a positive integer; and

each L¹ is independently a mono- or polydentate ligand different from ligands of formula

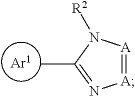

R¹ is a substituent;

z is 0 or a positive integer; and

X is O or S.

In a second aspect the invention provides a formulation comprising a composition according to the first aspect and at least one solvent.

In a third aspect the invention provides an organic light-emitting device comprising an anode, a cathode and a light-emitting layer between the anode and cathode wherein the light-emitting layer comprises a composition according to the first aspect.

### DESCRIPTION OF THE DRAWINGS

The invention will now be described in more detail with reference to the drawings in which:

FIG. 1 illustrates schematically an OLED according to an embodiment of the invention;

FIG. 2 shows the photoluminescence spectra of a composition according to an embodiment of the invention and two comparative compositions;

FIG. 3 is a graph of current density vs. voltage for an OLED according to an embodiment of the invention and a comparative OLED;

FIG. 4 is a graph of voltage vs. time for an OLED according to an embodiment of the invention and a comparative OLED;

FIG. 5 is a graph of EQE vs. current for an OLED according to an embodiment of the invention and a comparative OLED;

FIG. 6 is a graph of luminance vs. time for an OLED according to an embodiment of the invention and a comparative OLED; and

FIG. 7 shows the electroluminescent spectra of OLEDs according to embodiments of the invention.

### DETAILED DESCRIPTION OF THE INVENTION

FIG. 1 illustrates an OLED 100 according to an embodiment of the invention comprising an anode 101, a cathode 105 and a light-emitting layer 103 between the anode and cathode. The device 100 is supported on a substrate 107, for example a glass or plastic substrate.

Light-emitting layer 103 may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

Light-emitting layer 103 contains a composition of the invention. The light-emitting layer 103 may consist essentially of the composition or may contain one or more further materials, for example one or more charge-transporting materials or one or more further light-emitting materials. The polymer of the composition functions as a host for the compound of formula (I). The triplet energy level of the polymer is preferably no more than 0.1 eV below that of the phosphorescent compound of formula (I), and is more preferably about the same or higher than that of the phosphorescent compound in order to avoid quenching of phosphorescence from the phosphorescent compound. Optionally, the lowest triplet energy level of the host polymer is at least 2.5 eV, optionally at least 2.6 eV.

One or more further layers may be provided between the anode 101 and cathode 105, for example hole-transporting layers, electron transporting layers, hole blocking layers and electron blocking layers.

Preferred device structures include:

Anode/Hole-injection layer/Light-emitting layer/Cathode

Anode/Hole transporting layer/Light-emitting layer/Cathode

Anode/Hole-injection layer/Hole-transporting layer/Light-emitting layer/Cathode

Anode/Hole-injection layer/Hole-transporting layer/Light-emitting layer/Electron-transporting layer/Cathode.

Preferably, at least one of a hole-transporting layer and hole injection layer is present. Preferably, both a hole injection layer and hole-transporting layer are present.

In operation, substantially all light emitted from the device may be light emitted from the phosphorescent compound of formula (I), or one or more further fluorescent or phosphorescent light-emitting materials may be present.

In embodiments of the invention, substantially all light is emitted from a single light-emitting layer containing a composition of the invention. In other embodiments of the invention, the device may contain a light-emitting layer containing a composition of the invention and at least one further light-emitting layer. The further light-emitting layer may be a charge-transporting layer containing a fluorescent or phosphorescent light-emitting material that emits light when the device is in use.

The OLED may be a white-emitting OLED containing one or more further fluorescent or phosphorescent light-emitting materials that, in combination with the phosphorescent compound of formula (I), produce white light. A white-emitting OLED may contain a single, white-emitting layer or may contain two or more layers that emit different colours which, in combination, produce white light. White light may be produced from a combination of red, green and blue light-emitting materials provided in a single light-emitting layer or distributed within two or more light-emitting layers. In a preferred arrangement, the device has a light-emitting layer comprising a red light-emitting material and a light-emitting layer comprising green and blue light-emitting materials. The red light-emitting material may be provided as a dopant in a hole-transporting layer.

The light emitted from a white-emitting OLED may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-4500K.

The compound of formula (I) is preferably a blue phosphorescent compound. The photoluminescent spectrum of the phosphorescent compound of formula (I) may have a peak in the range of 420-490 nm, more preferably 420-480 nm.

If present in light-emitting layer 103 or in a separate layer, the one or more further light-emitting materials may be selected from green and red fluorescent or phosphorescent materials.

A green emitting material may have a photoluminescent spectrum with a peak in the range of more than 490 nm up to 580 nm, optionally more than 490 nm up to 540 nm.

A red emitting material may optionally have a peak in its photoluminescent spectrum of more than 580 nm up to 630 nm, optionally 585-625 nm.

In a preferred embodiment, the composition contains a blue phosphorescent compound of formula (I) and at least one of red and green phosphorescent compounds.

If present, a charge-transporting layer adjacent to a phosphorescent light-emitting layer preferably contains a charge-transporting material having a T₁ excited state energy level that is no more than 0.1 eV lower than, preferably the same as or higher than, the T₁ excited state energy level of the phosphorescent compound of formula (I) in order to avoid quenching of triplet excitons migrating from the light-emitting layer into the charge-transporting layer.

Triplet energy levels as described anywhere herein may be as measured from the energy onset (energy at half of the peak intensity on the high energy side) of the phosphorescence spectrum measured by low temperature phosphorescence spectroscopy (Y. V. Romaovskii et al, Physical Review Letters, 2000, 85 (5), p 1027, A. van Dijken et al, Journal of the American Chemical Society, 2004, 126, p 7718).

Phosphorescent Compound of Formula (I)

The phosphorescent compound of formula (I) may be physically mixed with the polymer or may be covalently bound thereto. The phosphorescent compound of formula (I) may be provided in a side-chain, main chain or end-group of the polymer. Where the phosphorescent material is provided in a polymer side-chain, the phosphorescent material may be directly bound to the backbone of the polymer or spaced apart there from by a spacer group, for example a C₁₋₂₀ alkyl spacer group in which one or more non-adjacent C atoms may be replaced by COO, C═O, O or S. It will therefore be appreciated that a composition of the present invention may consist of or may be a polymer comprising a repeat unit of formula (II) with a phosphorescent compound of formula (I) covalently bound in the polymer main chain or covalently bound as a side-group or end-group of the polymer.

The compound of formula (I) may make up about 0.05 wt % up to about 50 wt % of the phosphorescent compound+polymer weight.

If more than two phosphorescent materials of different colours are used with a single host material then the emitter with the highest triplet energy level may be provided in a greater amount than the other emitter or emitters, for example in an amount of at least two times or at least 5 times the weight percentage of each of the other emitter or emitters.

Optionally, y of formula (I) is 0.

In the case where y is at least 1, L¹ may be a diketonate, optionally acac or picolinate.

Optionally, x of formula (I) is 3.

Optionally, M of formula (I) is an iridium ion.

Ar¹ may be a fused or unfused group. Exemplary aromatic groups Ar¹ are phenyl that may be unsubstituted or substituted with 1, 2, 3, 4 or 5 substituents and fluorene that may be unsubstituted or substituted with one or more substituents. Exemplary heteroaromatic groups Ar¹ include pyridine and carbazole. Preferably, Ar¹ is a fused or unfused aromatic group.

Substituents of Ar¹, where present, may be selected from the group consisting of:
C₁₋₂₀ alkyl wherein one or more non-adjacent C atoms of the alkyl group may be replaced by O, S or COO, C═O, NR⁶ or SiR⁶₂ and one or more H atoms of the C₁₋₂₀ alkyl group may be replaced by F wherein R⁶ is a substituent and is optionally in each occurrence a C₁₋₄₀ hydrocarbyl group, optionally a C₁₋₂₀ alkyl group;
aryl or heteroaryl substituted with one or more C₁₋₂₀ alkyl groups; and
a branched or linear chain of two or more aryl or heteroaryl rings, each of which ring may be substituted with one or more substituents.

Exemplary C₁₋₂₀ alkyl groups wherein one or more non-adjacent C atoms of the alkyl group are replaced by O, S or COO, C═O, NR⁶ or SiR⁶₂ include C₁₋₂₀ alkoxy.

Preferably, substituents of Ar¹, where present, are selected from C₁₋₄₀ hydrocarbyl groups, more preferably from:
C₁₋₂₀ alkyl;
unsubstituted phenyl, or phenyl substituted with one or more C₁₋₂₀ alkyl groups; and
a branched or linear chain of two or more phenyl rings, each of which ring may be substituted with one or more C₁₋₂₀ alkyl groups.

A branched or linear chain of two or aryl or heteroaryl rings may be a dendron.

A dendron may have optionally substituted formula (XII)

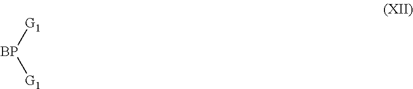

wherein BP represents a branching point for attachment to a core and G₁ represents first generation branching groups.

The dendron may be a first, second, third or higher generation dendron. G₁ may be substituted with two or more second generation branching groups G₂, and so on, as in optionally substituted formula (XIIa):

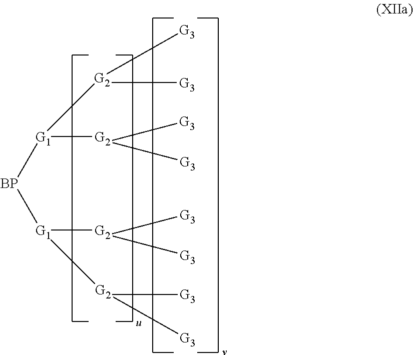

wherein u is 0 or 1; v is 0 if u is 0 or may be 0 or 1 if u is 1; BP represents a branching point for attachment to a core and G₁, G₂ and G₃ represent first, second and third generation dendron branching groups. In one preferred embodiment, each of BP and G₁, G₂ . . . Gₙ is phenyl, and each phenyl BP, G₁, G₂ . . . Gₙ₋₁ is a 3,5-linked phenyl.

BP and/or any group G may be substituted with one or more substituents, for example one or more C₁₋₂₀ alkyl or alkoxy groups.

Exemplary aromatic substituents of Ar¹ include the following, each of which may be unsubstituted or substituted with one or more substituents, optionally one, two or more C₁₋₂₀ alkyl groups:

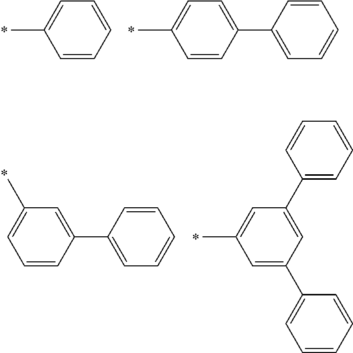

wherein * represents an attachment point of the dendron to Ar1.

Each R² may be selected from substituents of Ar¹ described above. R² is preferably a C₁₋₄₀ hydrocarbyl group as described above with reference to substituents of Ar¹.

In an embodiment, each A of formula (I) is CR³.

In another embodiment, one A of formula (I) is CR³ and the other A is N.

The heterocyclic ring containing the groups A is not fused.

R³, where present, is preferably selected from the group consisting of C₁₋₄₀ hydrocarbyl groups, more preferably C₁₋₂₀ alkyl.

Alkyl as described anywhere herein includes linear, branched and cyclic alkyl.

Polymer

The polymer comprising repeat units of formula (II) preferably has a LUMO level that is less than 2.1 eV from vacuum level. Preferably, the HOMO of the compound of formula (I) is at least 2.5 eV, optionally at least 2.7 eV deeper (further from vacuum) than the LUMO of the polymer. Without wishing to be bound by any theory, it is believed that this HOMO-LUMO gap reduces the probability of excimer formation between the HOMO of the compound of formula (I) and the LUMO of the polymer. It will be appreciated that a shallower LUMO of the polymer results in a larger HOMO-LUMO gap.

The polymer comprising repeat units of formula (II) is preferably a conjugated polymer wherein repeat units of formula (II) are conjugated to adjacent repeat units in the polymer backbone. The polymer may contain repeat units to limit the extent of conjugation along the polymer backbone.

Preferably, a polymer comprising repeat units of formula (II) is a co-polymer comprising repeat units of formula (II) and one or more co-repeat units.

Exemplary co-repeat units include arylene co-repeat units that may be unsubstituted or substituted with one or more substituents. A preferred arylene co-repeat unit is a phenylene repeat unit that may be unsubstituted or substituted with one or more substituents.

The one or more co-repeat units may include a conjugation-breaking repeat unit, which is a repeat unit that does not provide any conjugation path between repeat units adjacent to the conjugation-breaking repeat unit.

Exemplary conjugation-breaking co-repeat units include co-repeat units of formula (II):

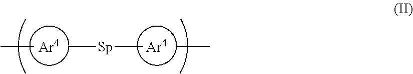

wherein:

Ar⁴ in each occurrence independently represents an aryl or heteroaryl group that may be unsubstituted or substituted with one or more substituents; and

Sp represents a spacer group comprising at least one carbon or silicon atom.

Preferably, the spacer group includes at least one sp³-hybridised carbon atom separating the Ar⁴ groups.

Preferably Ar⁴ is an aryl group and the Ar⁴ groups may be the same or different. More preferably each Ar⁴ is phenyl.

Each Ar⁴ may independently be unsubstituted or may be substituted with 1, 2, 3 or 4 substituents. The one or more substituents may be selected from:
C₁₋₂₀ alkyl wherein one or more non-adjacent C atoms of the alkyl group may be replaced by O, S or COO, C═O, NR⁶ or SiR⁶₂ and one or more H atoms of the C₁₋₂₀ alkyl group may be replaced by F wherein R⁶ is a substituent and is optionally in each occurrence a C₁₋₄₀ hydrocarbyl group, optionally a C₁₋₂₀ alkyl group; and
aryl or heteroaryl substituted with one or more C₁₋₂₀ alkyl groups.

Preferred substituents of Ar⁴ are C₁₋₂₀ alkyl groups, which may be the same or different in each occurrence.

Exemplary groups Sp include a C₁₋₂₀ alkyl chain wherein one or more non-adjacent C atoms of the chain may be replaced with O, S, —NR⁶—, —SiR⁶₂—, —C(═O)— or —COO— and wherein R⁶ in each occurrence is as described above.

Exemplary repeat units of formula (II) include the following, wherein R in each occurrence is H or C₁₅ alkyl:

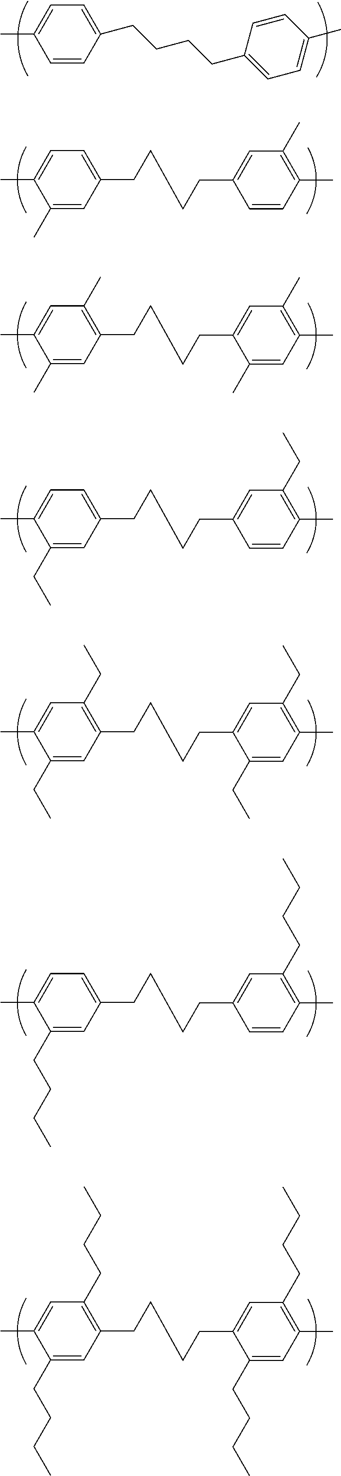

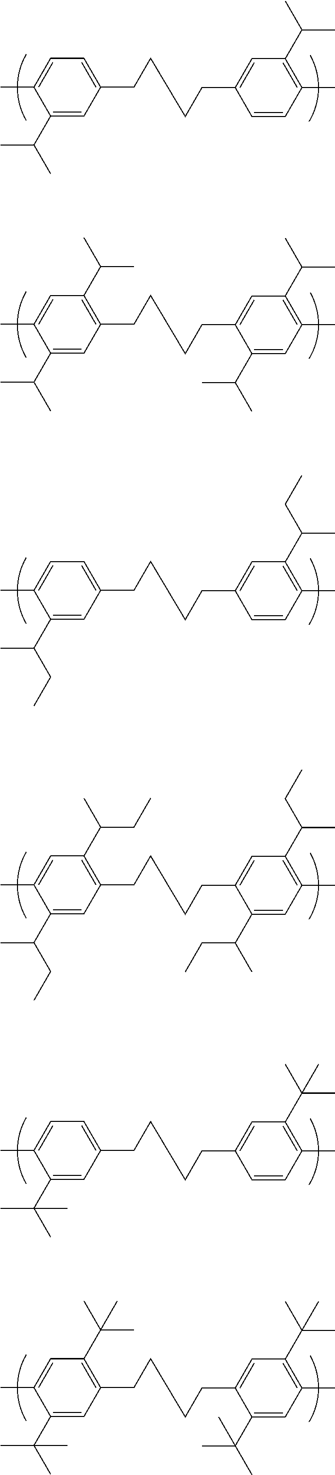

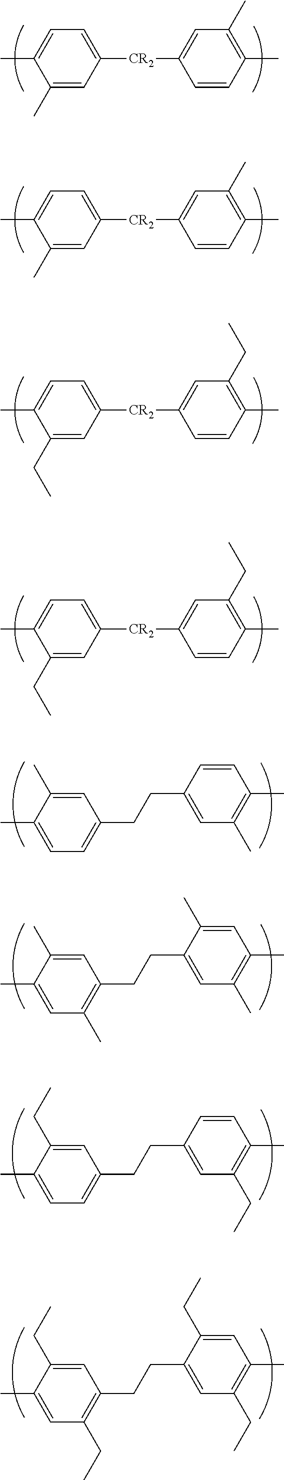

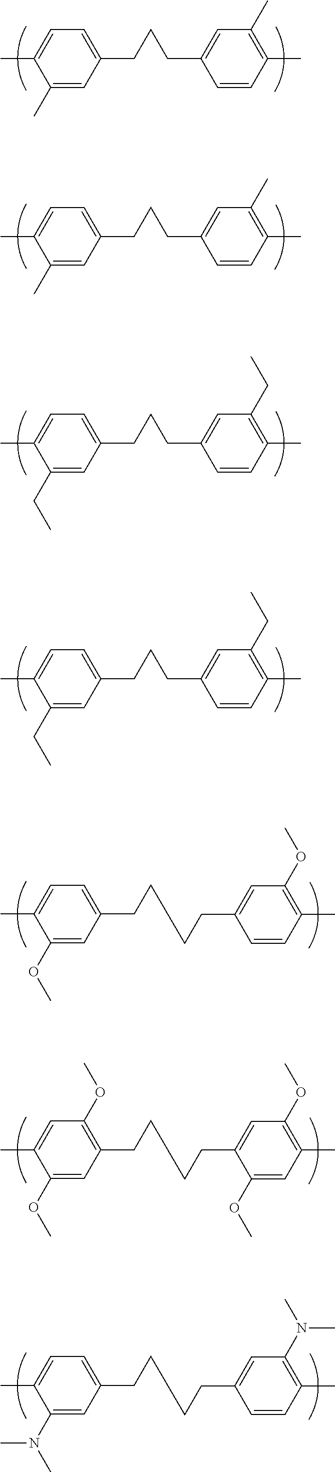

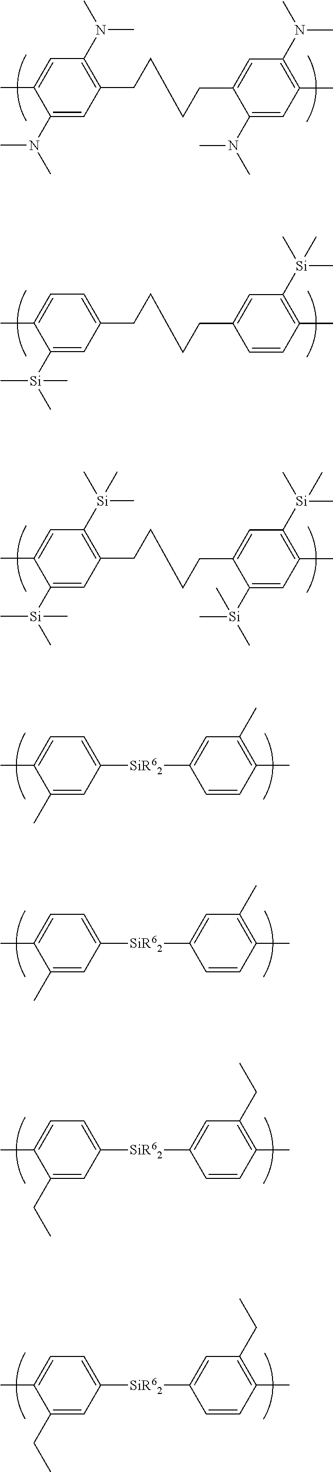

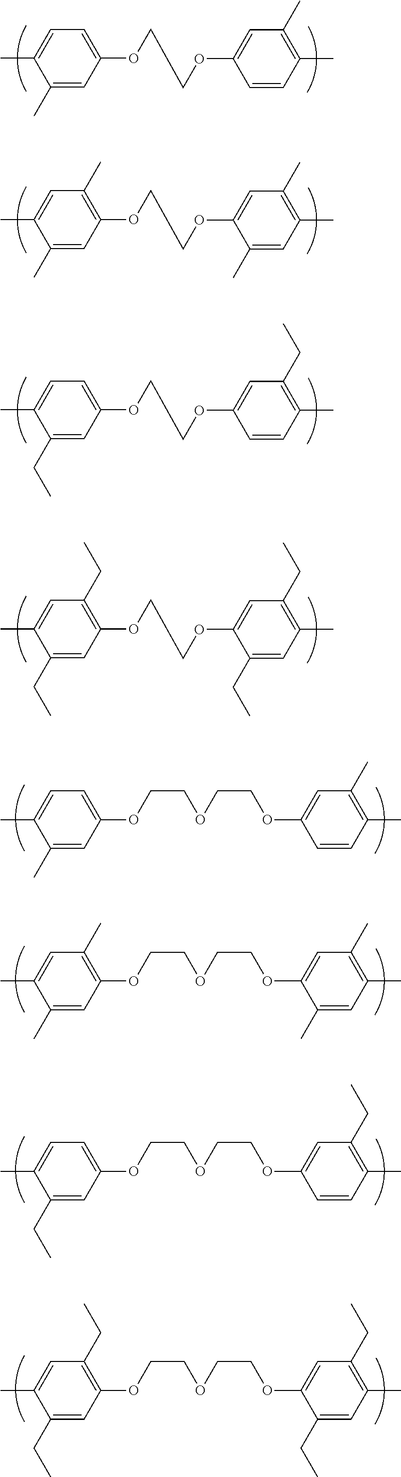

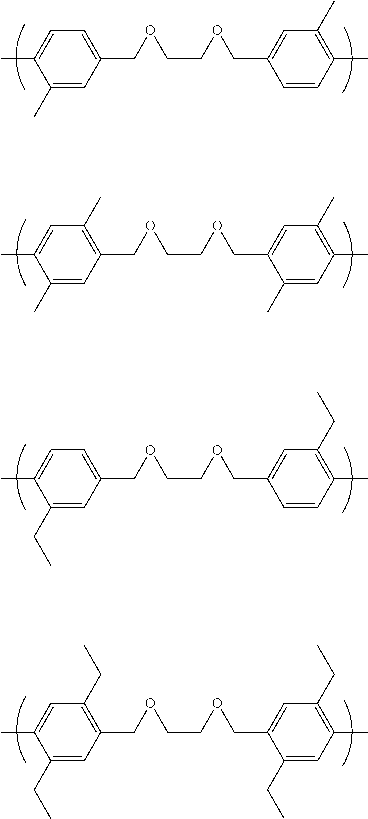

Exemplary arylene co-repeat units include 1,2-, 1,3- and 1,4-phenylene repeat units, 3,6- and 2,7-linked fluorene repeat units, indenofluorene, naphthalene, anthracene and phenanthrene repeat units, each of which may be unsubstituted or substituted with one or more substitutents, for example one or more C₁₋₄₀ hydrocarbyl substituents.

One preferred class of arylene repeat units is phenylene repeat units, such as phenylene repeat units of formula (VI):

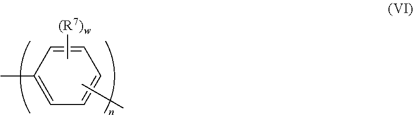

wherein w in each occurrence is independently 0, 1, 2, 3 or 4, optionally 1 or 2; n is 1, 2 or 3; and R⁷ independently in each occurrence is a substituent.

Where present, each R⁷ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
aryl and heteroaryl groups that may be unsubstituted or substituted with one or more substituents, preferably phenyl substituted with one or more C₁₋₂₀ alkyl groups;
a linear or branched chain of aryl or heteroaryl groups, each of which groups may independently be substituted, for example a group of formula —(Ar⁷)ᵣ wherein each Ar⁷ is independently an aryl or heteroaryl group and r is at least 2, preferably a branched or linear chain of phenyl groups each of which may be unsubstituted or substituted with one or more C₁₋₂₀ alkyl groups; and
a crosslinkable-group, for example a group comprising a double bond such and a vinyl or acrylate group, or a benzocyclobutane group.

In the case where R⁷ comprises an aryl or heteroaryl group, or a linear or branched chain of aryl or heteroaryl groups, the or each aryl or heteroaryl group may be substituted with one or more substituents R⁸ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F;
NR⁹₂, OR⁹, SR⁹, SiR⁹³ and
fluorine, nitro and cyano;

wherein each R⁹ is independently selected from the group consisting of alkyl, preferably C₁₋₂₀ alkyl; and aryl or heteroaryl, preferably phenyl, optionally substituted with one or more C₁₋₂₀ alkyl groups.

Substituted N, where present, may be —NR⁶— wherein R⁶ is as described above.

Preferably, each R⁷, where present, is independently selected from C₁₋₄₀ hydrocarbyl, and is more preferably selected from C₁₋₂₀ alkyl; unsubstituted phenyl; phenyl substituted with one or more C₁₋₂₀ alkyl groups; a linear or branched chain of phenyl groups, wherein each phenyl may be unsubstituted or substituted with one or more substituents; and a crosslinkable group.

If n is 1 then exemplary repeat units of formula (VI) include the following:

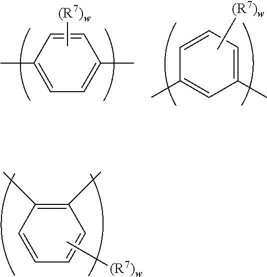

A particularly preferred repeat unit of formula (VI) has formula (VIa):

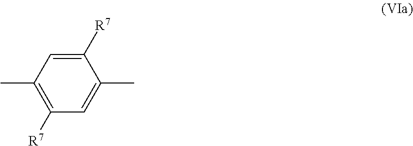

Substituents R⁷ of formula (VIa) are adjacent to linking positions of the repeat unit, which may cause steric hindrance between the repeat unit of formula (VIa) and adjacent repeat units, resulting in the repeat unit of formula (VIa) twisting out of plane relative to one or both adjacent repeat units.

Exemplary repeat units where n is 2 or 3 include the following:

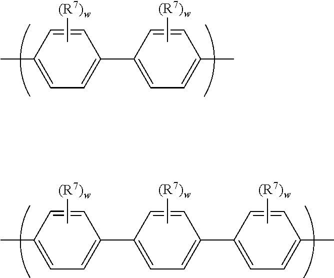

A preferred repeat unit has formula (VIb):

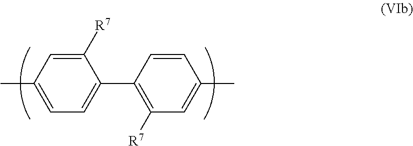

The two R⁷ groups of formula (VIb) may cause steric hindrance between the phenyl rings they are bound to, resulting in twisting of the two phenyl rings relative to one another.

A further class of arylene repeat units are optionally substituted fluorene repeat units, such as repeat units of formula (VII):

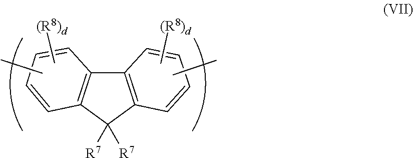

wherein R⁷ in each occurrence is the same or different and is a substituent as described with reference to formula (VI), and wherein the two groups R⁷ may be linked to form a ring; R⁸ is a substituent; and d is 0, 1, 2 or 3.

The aromatic carbon atoms of the fluorene repeat unit may be unsubstituted, or may be substituted with one or more substituents R⁸. Exemplary substituents R⁸ are alkyl, for example C₁₋₂₀ alkyl, wherein one or more non-adjacent C atoms may be replaced with O, S, NH or substituted N, C═O and —COO—, optionally substituted aryl, optionally substituted heteroaryl, alkoxy, alkylthio, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

Substituted N, where present, may be —NR⁶— wherein R⁶ is as described above.

The extent of conjugation of repeat units of formula (VII) to aryl or heteroaryl groups of adjacent repeat units in the polymer backbone may be controlled by (a) linking the repeat unit through the 3- and/or 6-positions to limit the extent of conjugation across the repeat unit, and/or (b) substituting the repeat unit with one or more substituents R⁸ in or more positions adjacent to the linking positions in order to create a twist with the adjacent repeat unit or units, for example a 2,7-linked fluorene carrying a C₁₋₂₀ alkyl substituent in one or both of the 3- and 6-positions.

The repeat unit of formula (VII) may be an optionally substituted 2,7-linked repeat unit of formula (VIIa):

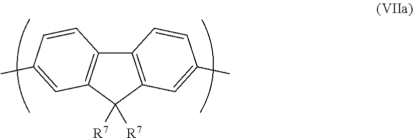

Optionally, the repeat unit of formula (VIIa) is not substituted in a position adjacent to the 2- or 7-position. Linkage through the 2- and 7-positions and absence of substituents adjacent to these linking positions provides a repeat unit that is capable of providing a relatively high degree of conjugation across the repeat unit.

The repeat unit of formula (VII) may be an optionally substituted 3,6-linked repeat unit of formula (VIIb)

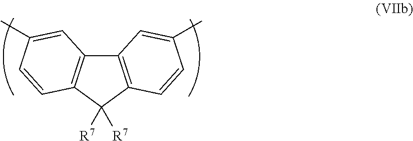

The extent of conjugation across a repeat unit of formula (VIIb) may be relatively low as compared to a repeat unit of formula (VIIa).

Another exemplary arylene repeat unit has formula (VIII):

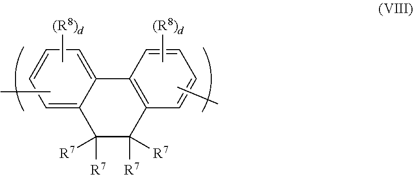

wherein R⁷, R⁸ and d are as described with reference to formula (VI) and (VII) above. Any of the R⁷ groups may be linked to any other of the R⁷ groups to form a ring. The ring so formed may be unsubstituted or may be substituted with one or more substituents, optionally one or more C₁₋₂₀ alkyl groups.

Repeat units of formula (VIII) may have formula (VIIIa) or (VIIIb):

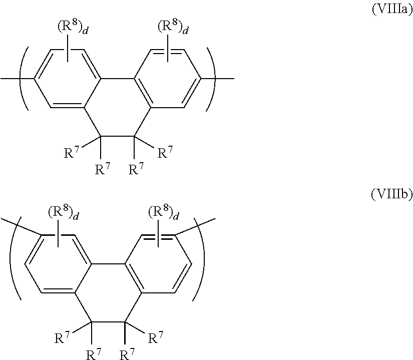

Further arylene co-repeat units include: phenanthrene repeat units; naphthalene repeat units; anthracene repeat units; and perylene repeat units. Each of these arylene repeat units may be linked to adjacent repeat units through any two of the aromatic carbon atoms of these units. Specific exemplary linkages include 9,10-anthracene; 2,6-anthracene; 1,4-naphthalene; 2,6-naphthalene; 2,7-phenanthrene; and 2,5-perylene. Each of these repeat units may be substituted or unsubstituted, for example substituted with one or more C₁₋₄₀ hydrocarbyl groups.

The polymer comprising a repeat unit of formula (II) may contain one or more hole transporting repeat units. Exemplary hole transporting repeat units may be repeat units of materials having a electron affinity of 2.9 eV or lower and an ionisation potential of 5.8 eV or lower, preferably 5.7 eV or lower.

Preferred hole-transporting repeat units are (hetero)arylamine repeat units, including repeat units of formula (IX):

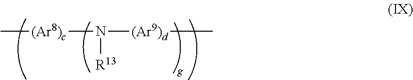

wherein Ar⁸ and Ar⁹ in each occurrence are independently selected from substituted or unsubstituted aryl or heteroaryl, g is greater than or equal to 1, preferably 1 or 2, R¹³ is H or a substituent, preferably a substituent, and c and d are each independently 1, 2 or 3.

R¹³, which may be the same or different in each occurrence when g>1, is preferably selected from the group consisting of alkyl, for example C₁₋₂₀ alkyl, Ar¹⁰, a branched or linear chain of Ar¹⁰ groups, or a crosslinkable unit that is bound directly to the N atom of formula (IX) or spaced apart therefrom by a spacer group, wherein Ar¹⁰ in each occurrence is independently optionally substituted aryl or heteroaryl. Exemplary spacer groups are C₁₋₂₀ alkyl, phenyl and phenyl-C₁₋₂₀ alkyl.

Any of Ar⁸, Ar⁹ and, if present, Ar¹⁰ in the repeat unit of Formula (IX) may be linked by a direct bond or a divalent linking atom or group to another of Ar⁸, Ar⁹ and Ar¹⁰. Preferred divalent linking atoms and groups include O, S; substituted N; and substituted C.

Any of Ar⁸, Ar⁹ and, if present, Ar¹⁰ may be substituted with one or more substituents. Exemplary substituents are substituents R¹⁰, wherein each R¹⁰ may independently be selected from the group consisting of:
substituted or unsubstituted alkyl, optionally C₁₋₂₀ alkyl, wherein one or more non-adjacent C atoms may be replaced with optionally substituted aryl or heteroaryl, O, S, substituted N, C═O or —COO— and one or more H atoms may be replaced with F; and
a crosslinkable group attached directly to the fluorene unit or spaced apart therefrom by a spacer group, for example a group comprising a double bond such and a vinyl or acrylate group, or a benzocyclobutane group

Preferred repeat units of formula (IX) have formulae 1-3:

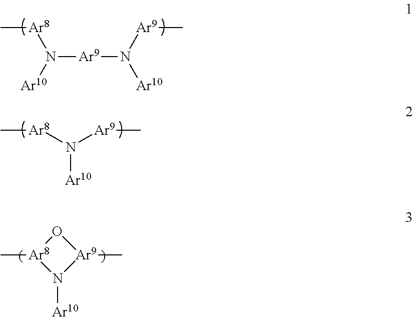

In one preferred arrangement, R¹³ is Ar¹⁰ and each of Ar⁸, Ar⁹ and Ar¹⁰ are independently and optionally substituted with one or more C₁₋₂₀ alkyl groups. Ar⁸, Ar⁹ and Ar¹⁰ are preferably phenyl.

In another preferred arrangement, the central Ar⁹ group of formula (IX) linked to two N atoms is a polycyclic aromatic that may be unsubstituted or substituted with one or more substituents R¹⁰. Exemplary polycyclic aromatic groups are naphthalene, perylene, anthracene and fluorene.

In another preferred arrangement, Ar⁸ and Ar⁹ are phenyl, each of which may be substituted with one or more C₁₋₂₀ alkyl groups, and R¹³ is —(Ar¹⁰)ᵣ wherein r is at least 2 and wherein the group —(Ar¹⁰)ᵣ forms a linear or branched chain of aromatic or heteroaromatic groups, for example 3,5-diphenylbenzene wherein each phenyl may be substituted with one or more C₁₋₂₀ alkyl groups. In another preferred arrangement, c, d and g are each 1 and Ar⁸ and Ar⁹ are phenyl linked by an oxygen atom to form a phenoxazine ring.

Amine repeat units may be provided in a molar amount in the range of about 0.5 mol % up to about 50 mol %, optionally about 1-25 mol %, optionally about 1-10 mol %.

The polymer may contain one, two or more different repeat units of formula (IX).

Amine repeat units may provide hole-transporting and/or light-emitting functionality. Preferred light-emitting amine repeat units include a blue light-emitting repeat unit of formula (IXa) and a green light-emitting repeat unit formula (IXb):

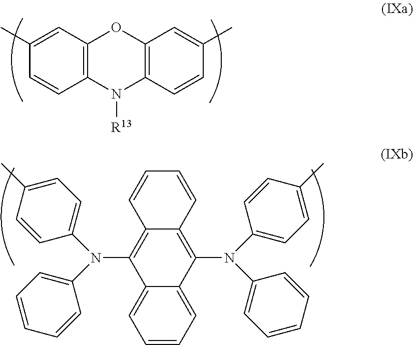

R¹³ of formula (IXa) is preferably a hydrocarbyl, preferably C₁₋₂₀ alkyl, phenyl that is unsubstituted or substituted with one or more C₁₋₂₀ alkyl groups, or a branched or linear chain of phenyl groups wherein each said phenyl group is unsubstituted or substituted with one or more C₁₋₂₀ alkyl groups.

The repeat unit of formula (IXb) may be unsubstituted or one or more of the rings of the repeat unit of formula (IXb) may be substituted with one or more substituents R⁵, preferably one or more C₁₋₂₀ alkyl groups.

In one arrangement the phosphorescent material of the composition according to the invention is mixed with the polymer.

In another arrangement the phosphorescent material of the composition according to the invention is covalently bound to the polymer. In this arrangement, the phosphorescent material may be provided as a main-chain repeat unit of the polymer backbone, an end-group of the polymer or a side-group of the polymer that may be directly bound to the polymer backbone or spaced apart from the polymer backbone by a spacer group, for example a C₁₋₂₀ alkyl group.

Optionally, a light-emitting layer of an OLED according to the invention is formed by depositing a formulation according to the invention comprising the composition and at least one solvent, and evaporating the at least one solvent.

Polymers as described herein suitably have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of the polymers described herein may be 1×10³ to 1×10⁸, and preferably 1×10⁴ to 1×10⁷.

Polymers described herein are suitably amorphous polymers.

Polymer Synthesis

One method of forming conjugated or partially conjugated polymers is Suzuki polymerisation, for example as described in WO 00/53656 or U.S. Pat. No. 5,777,070 which allows formation of C—C bonds between two aromatic or heteroaromatic groups, and so enables formation of polymers having conjugation extending across two or more repeat units.

Suzuki polymerisation takes place in the presence of a palladium complex catalyst and a base.

As illustrated in Scheme 1, in the Suzuki polymerisation process a monomer for forming repeat units RU1 having leaving groups LG1 such as boronic acid or boronic ester groups undergoes polymerisation with a monomer for forming repeat units RU2 having leaving groups LG2 such as halogen, sulfonic acid or sulfonic ester to form a carbon-carbon bond between Arylene 1 and Arylene 2:

nLG1-RU1-LG1+nLG2-RU2-LG2-→-(RU1-RU2)ₙ-

Scheme 1

Exemplary boronic esters have formula (V):

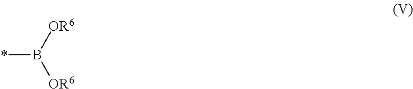

wherein R⁶ in each occurrence is independently a C₁₋₂₀ alkyl group, * represents the point of attachment of the boronic ester to an aromatic ring of the monomer, and the two groups R⁶ may be linked to form a ring. In a preferred embodiment, the two groups R⁶ are linked to form the pinacol ester of boronic acid:

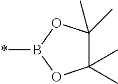 [SMILES: *B1OC(C)(C)C(C)(C)O1]

It will be understood by the skilled person that a monomer LG1-RU1-LG1 will not polymerise to form a direct carbon-carbon bond with another monomer LG1-RU1-LG1. A monomer LG2-RU2-LG2 will not polymerise to form a direct carbon-carbon bond with another monomer LG2-RU2-LG2.

Preferably, one of LG1 and LG2 is bromine or iodine and the other is a boronic acid or boronic ester.

This selectivity means that the ordering of repeat units in the polymer backbone can be controlled such that all or substantially all RU1 repeat units formed by polymerisation of LG1-RU1-LG1 are adjacent, on both sides, to RU2 repeat units.

In the example of Scheme 1 above, an AB copolymer is formed by copolymerisation of two monomers in a 1:1 ratio, however it will be appreciated that more than two or more than two monomers may be used in the polymerisation, and any ratio of monomers may be used.

The base may be an organic or inorganic base. Exemplary organic bases include tetra-alkylammonium hydroxides, carbonates and bicarbonates. Exemplary inorganic bases include metal (for example alkali or alkali earth) hydroxides, carbonates and bicarbonates.

The palladium complex catalyst may be a palladium (0) or palladium (II) compound.

Particularly preferred catalysts are tetrakis(triphenylphosphine)palladium (0) and palladium (II) acetate mixed with a phosphine.

A phosphine may be provided, either as a ligand of the palladium compound catalyst or as a separate compound added to the polymerisation mixture. Exemplary phosphines include triarylphosphines, for example triphenylphosphines wherein each phenyl may independently be unsubstituted or substituted with one or more substituents, for example one or more C₁₅ alkyl or C₁₅ alkoxy groups.

Particularly preferred are triphenylphosphine and tris(ortho-methoxytriphenyl) phosphine.

The polymerisation reaction may take place in a single organic liquid phase in which all components of the reaction mixture are soluble. The reaction may take place in a two-phase aqueous-organic system, in which case a phase transfer agent may be used. The reaction may take place in an emulsion formed by mixing a two-phase aqueous-organic system with an emulsifier.

The polymer may be end-capped by addition of an endcapping reactant. Suitable end-capping reactants are aromatic or heteroaromatic materials substituted with only one leaving group. The end-capping reactants may include reactants substituted with a halogen for reaction with a boronic acid or boronic ester group at a polymer chain end, and reactants substituted with a boronic acid or boronic ester for reaction with a halogen at a polymer chain end. Exemplary end-capping reactants are halobenzenes, for example bromobenzene, and phenylboronic acid. End-capping reactants may be added during or at the end of the polymerisation reaction.

Charge Transporting and Charge Blocking Layers

A hole transporting layer may be provided between the anode and the light-emitting layer or layers of an OLED. Likewise, an electron transporting layer may be provided between the cathode and the light-emitting layer or layers.

Similarly, an electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A charge-transporting layer or charge-blocking layer may be cross-linked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group.

If present, a hole transporting layer located between the anode and the light-emitting layers preferably has a HOMO level of less than or equal to 5.5 eV, more preferably around 4.8-5.5 eV or 5.1-5.3 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

If present, an electron transporting layer located between the light-emitting layers and cathode preferably has a LUMO level of around 2.5-3.5 eV as measured by cyclic voltammetry. For example, a layer of a silicon monoxide or silicon dioxide or other thin dielectric layer having thickness in the range of 0.2-2 nm may be provided between the light-emitting layer nearest the cathode and the cathode. HOMO and LUMO levels may be measured using cyclic voltammetry.

A hole transporting layer may contain a homopolymer or copolymer comprising a repeat unit of formula (IX) as described above, for example a copolymer comprising one or more amine repeat units of formula (IX) and one or more arylene repeat units, for example one or more arylene repeat units selected from formulae (VI), (VII) and (VIII).

An electron transporting layer may contain a polymer comprising a chain of optionally substituted arylene repeat units, such as a chain of fluorene repeat units.

If a hole- or electron-transporting layer is adjacent a light-emitting layer containing a phosphorescent material then the T₁ energy level of the material or materials of that layer are preferably higher than that of the phosphorescent emitter in the adjacent light-emitting layer.

Hole Injection Layers

A conductive hole injection layer, which may be formed from a conductive organic or inorganic material, may be provided between the anode 101 and the light-emitting layer 103 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

Cathode

The cathode 105 is selected from materials that have a workfunction allowing injection of electrons into the light-emitting layer of the OLED. Other factors influence the selection of the cathode such as the possibility of adverse interactions between the cathode and the light-emitting material. The cathode may consist of a single material such as a layer of aluminium. Alternatively, it may comprise a plurality of conductive materials such as metals, for example a bilayer of a low workfunction material and a high workfunction material such as calcium and aluminium, for example as disclosed in WO 98/10621. The cathode may comprise elemental barium, for example as disclosed in WO 98/57381, Appl. Phys. Lett. 2002, 81(4), 634 and WO 02/84759. The cathode may comprise a thin (e.g. 0.5-5 nm) layer of metal compound, in particular an oxide or fluoride of an alkali or alkali earth metal, between the organic layers of the device and one or more conductive cathode layers to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Encapsulation

Organic optoelectronic devices tend to be sensitive to moisture and oxygen.

Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

Formulation Processing

A formulation suitable for forming a light-emitting layer may be formed from the composition or the polymer of the invention, any further components of the layer such as light-emitting dopants, and one or more suitable solvents.

The formulation may be a solution of the composition and any other components in the one or more solvents, or may be a dispersion in the one or more solvents in which one or more components are not dissolved. Preferably, the formulation is a solution.

Solvents suitable for dissolving polymers or phosphorescent compounds carrying non-polar substituents such as alkyl substituents, include benzenes substituted with one or more C₁₋₁₀ alkyl or C₁₋₁₀ alkoxy groups, for example toluene, xylenes and methylanisoles.

Particularly preferred solution deposition techniques including printing and coating techniques such spin-coating and inkjet printing.

Spin-coating is particularly suitable for devices wherein patterning of the light-emitting layer is unnecessary—for example for lighting applications or simple monochrome segmented displays.

Inkjet printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing, screen printing and slot-die coating.

### EXAMPLES

### Monomer Example 1

To a solution of dibenzothiophene (50 g, 0.271 mol) in 300 ml of chloroform and 300 ml acetic acid was added drop wise bromine (41.8 ml, 0.814 mol) in solution in 40 ml chloroform at 0° C. The resulting mixture was allowed to warm up slowly to room temperature and stirred for 48 hours. GC-MS showed no starting material, mixture of mono and dibromide+some isomers. Reaction mixture was stirred at room temperature for extra 24 hours.

Reaction mixture was quenched by adding drop wise 500 ml of an aqueous solution of sodium hydroxide (20% wt/v) at 0° C. Mixture was then poured into 2.5 L of methanol. Slurry was stirred for 1 hour and filtered. The solid was the triturated for 30 minutes in 1 L of methanol, filtered and dried over the week end in vacuum oven at 50° C. Solid was stirred in 800 ml of refluxing chloroform for 2 hours and filtered. Resulting solid was stirred in 500 ml of refluxing chloroform for 2 hours and filtered. Solid was then recrystallised 3 times from a mixture of toluene:chloroform to reach the desired purity (99.64% by HPLC, 26.4 g of white solid, 28% yield).

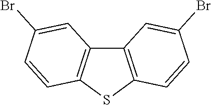 [SMILES: Brc1ccc2sc3ccc(Br)cc3c2c1]

### Monomer Example 2

To a solution of dibenzofuran (50 g, 0.298 mol) in 300 ml of chloroform was added drop wise bromine (35.2 ml, 0.684 mol) in solution in 40 ml chloroform at 0° C. The resulting mixture was allowed to warm up slowly to room temperature and stirred for 24 hours. GC-MS showed no starting material, mixture of mono and dibromide+some isomers.

Reaction mixture was cooled down to 0° C. and bromine (7.6 ml, 0.148 mol) in solution in 10 ml chloroform was added. The resulting mixture was allowed to warm up slowly to room temperature and stirred for 24 hours. GC-MS: 25% monobromide, 70% dibromide+isomers, 2% tribromide. Reaction mixture was cooled down to 0° C. and bromine (3.0 ml, 0.059 mol) in solution in 5 ml chloroform was added. The resulting mixture was allowed to warm up slowly to room temperature and stirred over night.

Reaction mixture was quenched by adding drop wise 300 ml of an aqueous solution of sodium hydroxide (20% wt/v) at 0° C. Mixture was then poured into 3 L of methanol. Slurry was stirred for 2 hours and filtered. The solid was the triturated for 1 hour in 1 L of methanol, filtered and dried over night in vacuum oven at 50° C. Solid was suspended in 100 ml of refluxing chloroform, 600 ml methanol was added followed by 500 ml toluene.

No full dissolution but mixture was left to cool down to room temperature and filtered. Solid was then recrystallised from a mixture of toluene:methanol, and finally recrystallised from a mixture of toluene:hexane to reach the desired purity (99.73% by HPLC, 32.5 g of white solid, 33% yield).

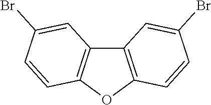 [SMILES: Brc1ccc2oc3ccc(Br)cc3c2c1]

### Polymer Examples

Polymers were prepared by Suzuki polymerisation as described in WO 00/53656 of monomers illustrated below in the amounts shown in Table 1.

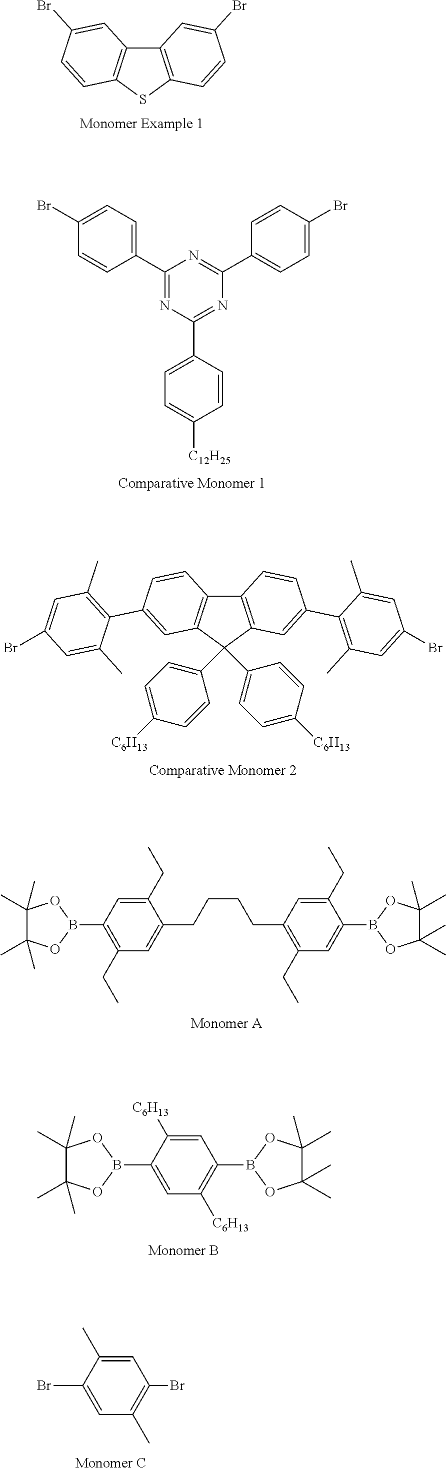

Lowest excited triplet state (T¹) energy levels of the polymers were measured by time-resolved photoluminescence spectroscopy.

TABLE 1

| | Boronic ester | | LUMO |
|---|---|---|---|
| | monomer | | level |
| Polymer | (mol %) | Dibromo monomer (mol %) | (eV) |
| Polymer | Monomer A (15) | Monomer Example 1 (50) | 1.85 |
| Example 1 | Monomer B (35) | | |
| Comparative | Monomer A (50) | Comparative Monomer 1 (45) | 2.61 |
| Polymer 1 | | Monomer C (5) | |
| Comparative | Monomer B (50) | Comparative Monomer 2 (50) | 1.7 |
| Polymer 2 | | | |
| Polymer | Monomer A (15) | Monomer Example 2 (50) | 1.82 |
| Example 2 | Monomer B (35) | | |

### Composition Example

A polymer and Blue Phosphorescent Emitter 1 (95 polymer: 5 emitter weight %) were dissolved in a solvent and the formulation was deposited by spin-coating onto a quartz substrate. The solvent was evaporated and the photoluminescent spectrum of the resultant film was measured.

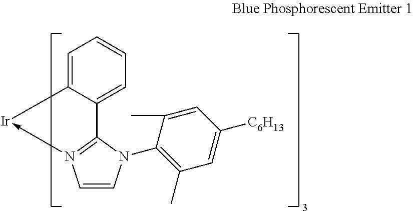

Phosphorescent Emitter 1 has a HOMO level of 4.82 eV and a LUMO level of 1.86 eV

TABLE 2

| | Polymer of the | Emitter HOMO - Host |
|---|---|---|
| Composition | composition | LUMO gap (eV) |
| Composition | Polymer Example 1 | 2.97 |
| Example 1 | | |
| Comparative | Comparative Polymer 1 | 2.21 |
| Composition 1 | | |
| Comparative | Comparative Polymer 2 | 3.12 |
| Composition 2 | | |

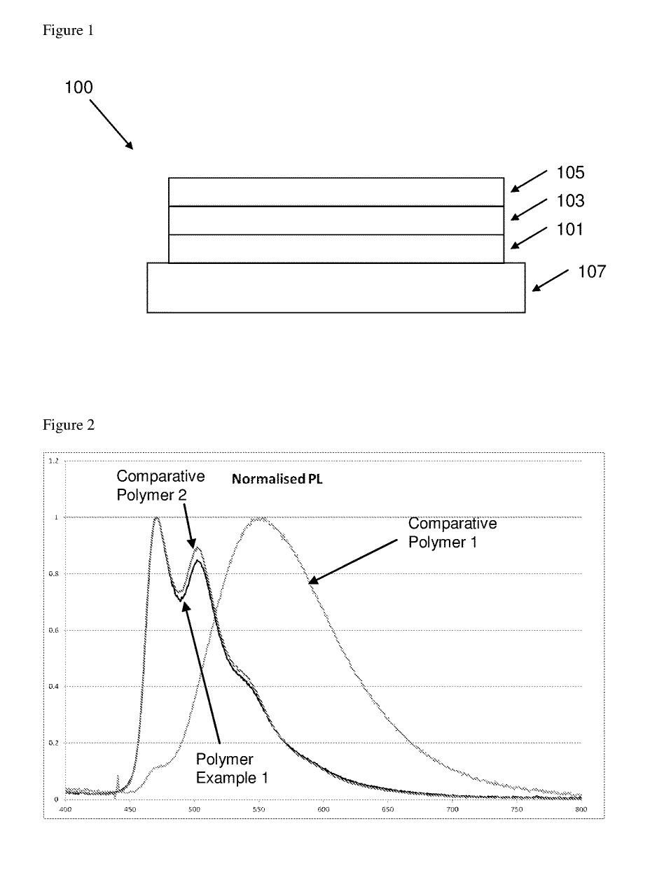

With reference to the photoluminescent spectra of FIG. 2, the peak wavelength of Comparative Composition 1 is at a considerably longer wavelength than, and significantly broader than, that of either Composition Example 1 or Comparative Composition 2. Without wishing to be bound by any theory, it is believed that the relatively small emitter HOMO—host LUMO gap of Comparative Composition 1 results in exciplex formation, whereas the gaps of Composition Example 1 and Comparative Composition 2 are sufficiently large to avoid significant exciplex formation.

### Device Example 1

A white organic light-emitting device having the following structure was prepared:

ITO/HIL/HTL/LEL/Cathode

wherein ITO is an indium-tin oxide anode; HIL is a hole-injecting layer comprising a hole-injecting material, HTL is a hole-transporting layer, and LEL is a light-emitting layer containing light-emitting metal complexes and a host polymer.

A substrate carrying ITO was cleaned using UV/Ozone. A hole injection layer was formed to a thickness of about 35 nm by spin-coating an aqueous formulation of a hole-injection material available from Plextronics, Inc. A red-emitting hole transporting layer was formed to a thickness of about 22 nm by spin-coating a crosslinkable red-emitting hole-transporting polymer and crosslinking the polymer by heating.

The red-emitting hole transporting polymer was formed by Suzuki polymerisation as described in WO 00/53656 of the following monomers:

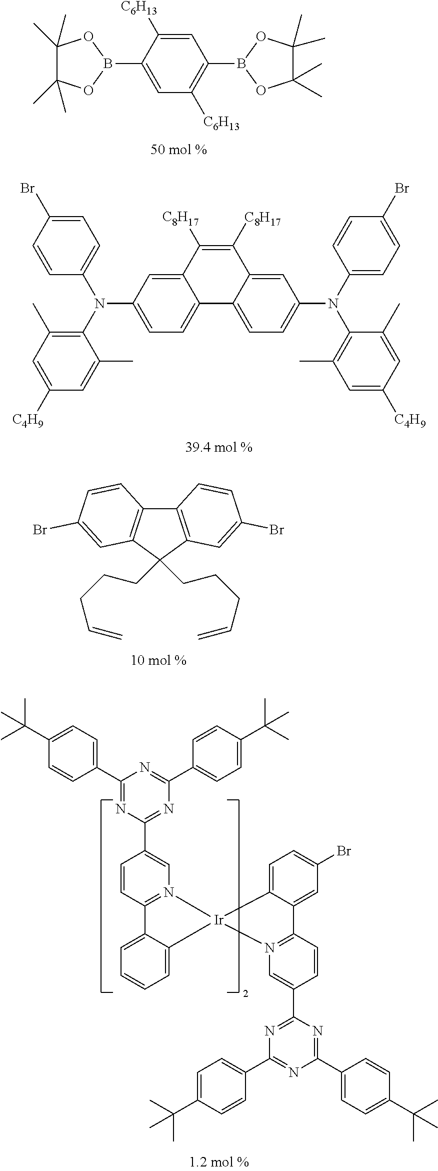

The hole transport polymer has the following molecular weight characteristics (GPC relative to polystyrene standard, in Dalton): Mw 129,000, Mp 128,000, Mn 37,000, Pd 3.53.

A green and blue light emitting layer was formed by depositing a light-emitting composition containing Polymer Example 1(74 wt %) doped with Green Phosphorescent Emitter 1 (1 wt %) and Blue Phosphorescent Emitter 2 (25 wt %), illustrated below, to a thickness of about 75 nm by spin-coating. An electron-injecting layer was formed by spin-coating Electron Injecting Polymer 1, as described in WO 2012/133229. A cathode was formed by evaporation of a layer of sodium fluoride to a thickness of about 2 nm, a second layer of aluminium to a thickness of about 100 nm and a third layer of silver to a thickness of about 100 nm.

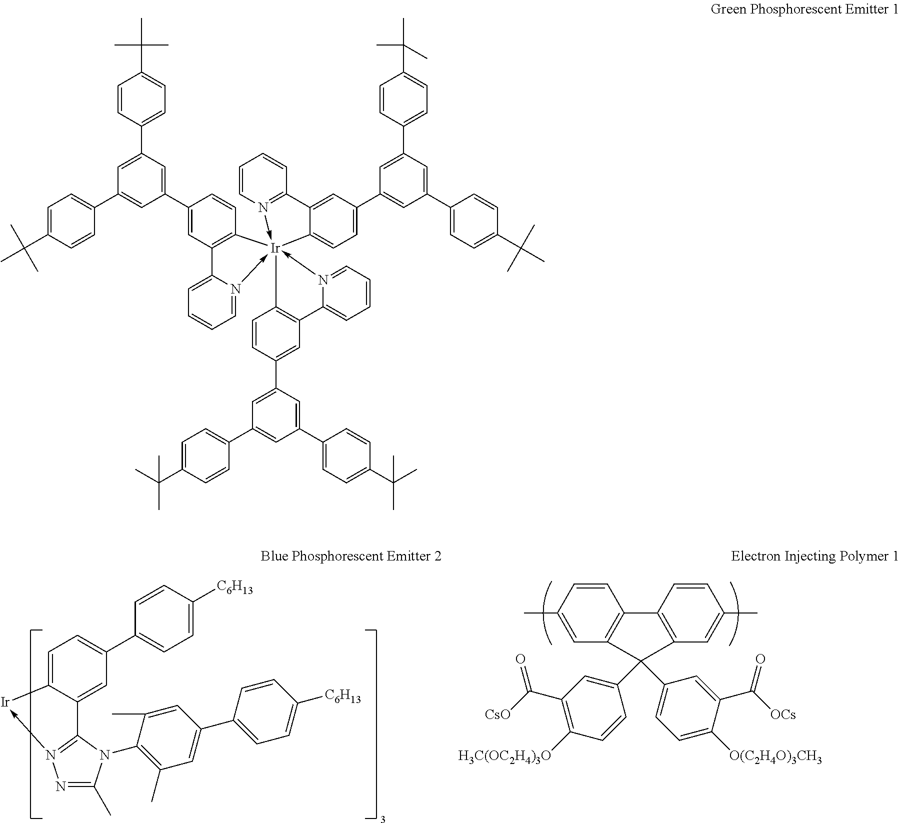

### Comparative Device 1

For the purpose of comparison, a device was formed as described with reference to Device Example 1 except that Polymer Example 1 was replaced with Comparative Polymer 2.

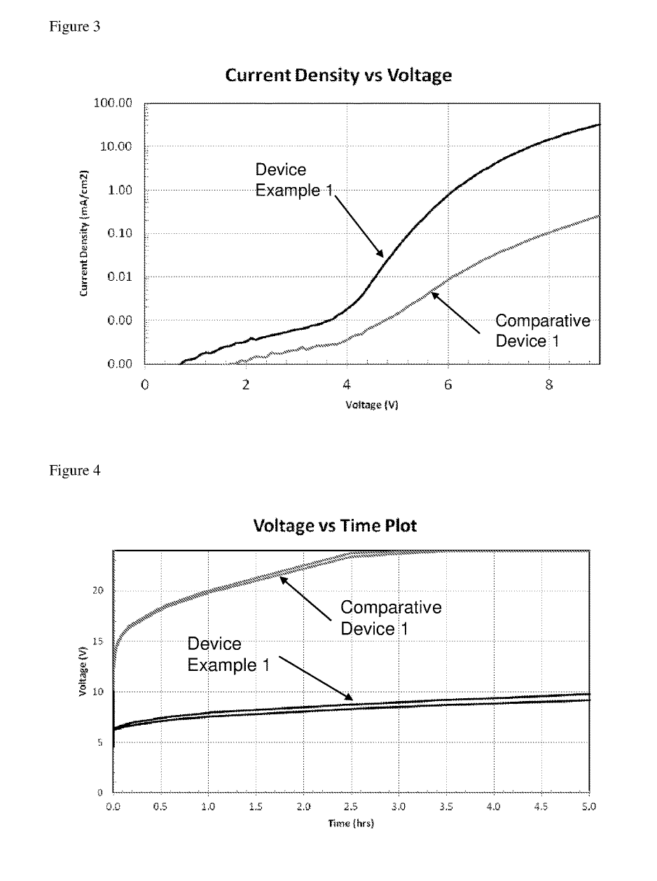

With reference to FIG. 3, current density for any voltage between 1-9V is higher for Device Example 1 than for Comparative Device 1.

With reference to FIG. 4, Device Example 1 operates at a lower voltage and voltage rise over time is smaller than for Comparative Device 1.

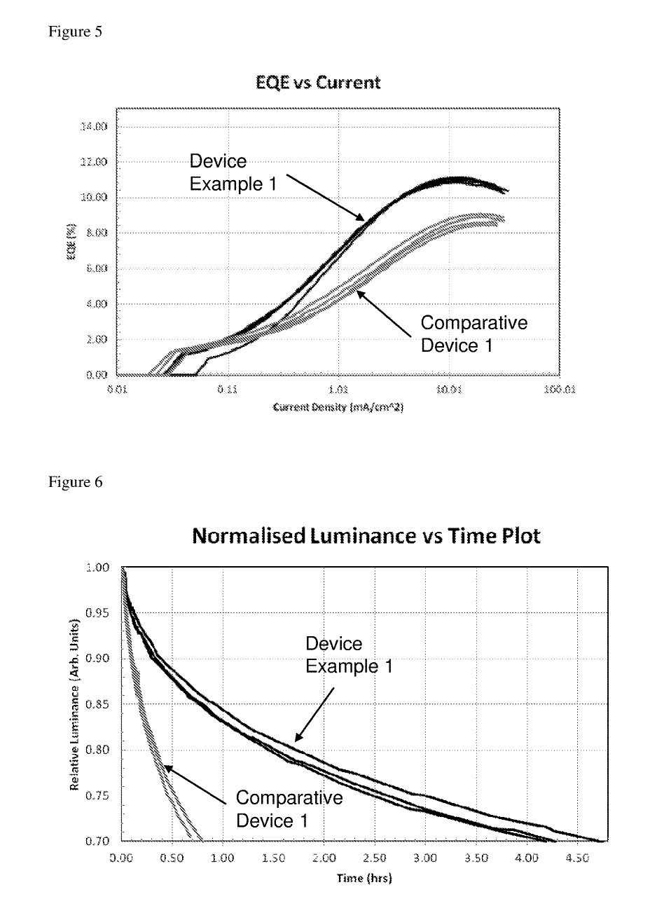

With reference to FIG. 5, external quantum efficiency at a given current for Device Example 1 is similar to or higher than that of Comparative Device 1.

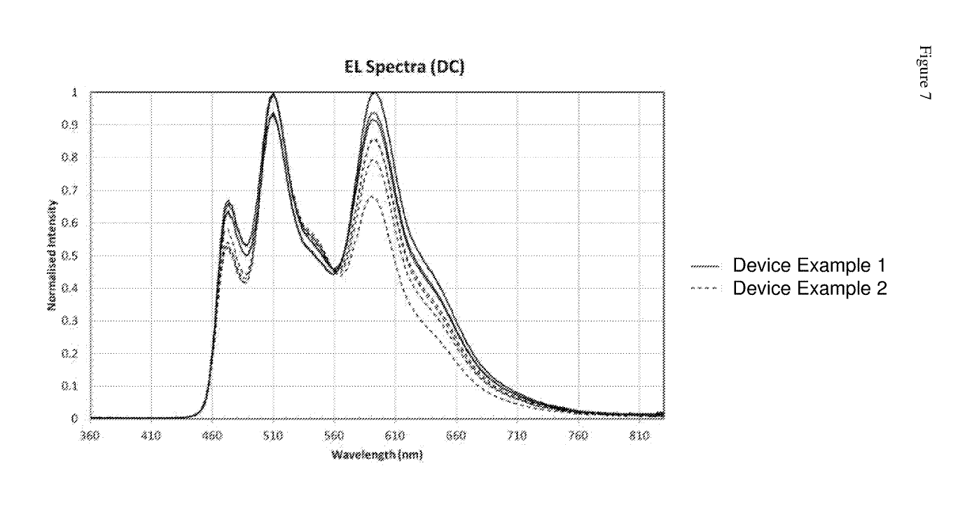

With reference to FIG. 6, the time taken for Device Example 1 to decay to 70% of a starting brightness at constant current is significantly longer than for Comparative Device 1.

### Device Example 2

A device was prepared as described in Device Example 1 except that the green and blue light emitting layer was formed by depositing a light-emitting composition containing Polymer Example 2 (74 wt %) doped with Green Phosphorescent Emitter 1 (1 wt %) and Blue Phosphorescent Emitter 2 (25 wt %).

With reference to FIG. 7, electroluminescent spectra of Device Examples 1 and 2 are similar.

With reference to Table 3, conductivities and efficiencies of Device Examples 1 and 2 are similar.

TABLE 3

| | Voltage | | | Efficiency | Efficiency | EQE at | Max |
|---|---|---|---|---|---|---|---|
| | at 1000 cd/m² | J at 1000 cd/m² | V at 10 ma/cm² | at 1000 cd/m² | at 1000 cd/m² | 1000 cd/m² | EQE |
| Polymer | (V) | (ma/cm²) | (V) | (Lm/W) | (Lm/W) | (%) | (%) |
| Device | 7.41 | 3.6 | 8.45 | 11.58 | 27.93 | 11.60 | 13.5 |
| Example 1 | | | | | | | |
| Device | 7.47 | 3.6 | 8.50 | 11.26 | 27.80 | 11.03 | 13.7 |
| Example 2 | | | | | | | |

The time taken for brightness of Device Example 1 to fall to 50% of a starting brightness was approximately 50% longer than for Device Example 2.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A composition comprising a phosphorescent compound of formula (I) and a polymer comprising a repeat unit of formula (II) 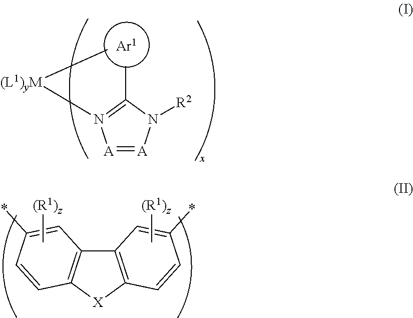
wherein:
Ar¹ is an aryl or heteroaryl group that may be unsubstituted or substituted with one or more substituents;
R² is a substituent;
A is independently in each occurrence N or CR³ wherein R³ is H or a substituent;
M is a transition metal or metal ion;
x is a positive integer of at least 1;
y is 0 or a positive integer; and
each L is independently a mono- or polydentate ligand different from ligands of formula 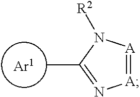
R¹ is a substituent;
z is 0 or a positive integer; and
X is O or S.

2. The composition according to claim 1, wherein y=0.

3. The composition according to claim 1, wherein x=3.

4. The composition according to claim 1, wherein M is an iridium ion.

5. The composition according to claim 1, wherein Ar¹ is phenyl that may be unsubstituted or substituted with one or more substituents.

6. The composition according to claim 1, wherein each A is CR³.

7. The composition according to claim 1, wherein one A is CR³ and the other A is N.

8. The composition according to claim 1, wherein the polymer has a LUMO level less than 2.0 eV from vacuum level.

9. The composition according to claim 1, wherein the polymer comprises one or more co-repeat units.

10. The composition according to claim 9, wherein the polymer comprises an arylene co-repeat unit that may be unsubstituted or substituted with one or more substituents.

11. The composition according to claim 9, wherein the one or more co-repeat units include a conjugation-breaking repeat unit that does not provide any conjugation path between repeat units adjacent to the conjugation-breaking repeat unit.

12. The composition according to claim 11, comprising one or more co-repeat units of formula (III): 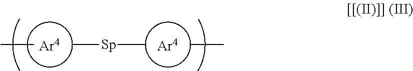
wherein:
Ar⁴ in each occurrence independently represent an aryl or heteroaryl group that may be unsubstituted or substituted with one or more substituents; and
Sp represents a spacer group comprising at least one carbon or silicon atom.

13. The composition according to claim 1, wherein the compound of formula (I) is mixed with the polymer.

14. The composition according to claim 1, wherein the compound of formula (I) is covalently bound to the polymer.

15. The composition according to claim 1, wherein the phosphorescent material has a photoluminescent spectrum with a peak in the range of 420-490 nm.

16. A formulation comprising a composition according to claim 1, and at least one solvent.

17. An organic light-emitting device comprising an anode, a cathode and a light-emitting layer between the anode and cathode wherein the light-emitting layer comprises a composition according to claim 1.

18. The organic light-emitting device according to claim 17, wherein the device comprises a further light-emitting layer between the anode and the cathode.

19. The organic light-emitting device according to claim 17, wherein the device emits white light.
